(19) United States
(12) Patent Application Publication
(10) Pub. No.: US 2012/0067422 A1
(43) Pub. Date: Mar. 22, 2012

(54) PHOTOVOLTAIC DEVICE WITH A METAL SULFIDE OXIDE WINDOW LAYER

(75) Inventors: Rui Shao, Sylvania, OH (US); Markus Gloeckler, Perrysburg, OH (US); Benyamin Buller, Perrysburg, OH (US)

(73) Assignee: FIRST SOLAR, INC, Perrysburg, OH (US)

(21) Appl. No.: 13/240,101

(22) Filed: Sep. 22, 2011

Related U.S. Application Data
(60) Provisional application No. 61/385,420, filed on Sep. 22, 2010.

(51) Int. Cl. H01L 31/0296; H01L 31/0272; H01L 31/0336; H01L 31/18

(52) U.S. Cl. 136/260; 438/85; 136/265; 136/262; 136/261; 136/252; 257/E31.015

(57) ABSTRACT

Methods and devices are described for a photovoltaic device and substrate structure. In one embodiment, a photovoltaic device includes a substrate structure and a MS ₁₋ₓOx window layer formed over the substrate structure, wherein M is an element from the group consisting of Zn, Sn, and In. Another embodiment is directed to a process for manufacturing a photovoltaic device including forming a MS ₁₋ₓOₓ window layer over a substrate by at least one of sputtering, evaporation deposition, CVD, chemical bath deposition process and vapor transport deposition process, wherein M is an element from the group consisting of Zn, Sn, and In.

### CROSS REFERENCE TO RELATED APPLICATION

This application claims priority under 35 U.S.C. §119(e) to Provisional Application No. 61/385,420 filed on Sep. 22, 2010, which is hereby incorporated by reference in its entirety.

### FIELD OF THE INVENTION

Embodiments of the invention relate to semiconductor devices and methods of manufacture, and more particularly to the field of photovoltaic (PV) devices.

### BACKGROUND OF THE INVENTION

Photovoltaic devices generally comprise multiple layers of material deposited on a substrate, such as glass. FIG. 1 depicts a typical photovoltaic device. Photovoltaic device 100 may employ a glass substrate 105, a transparent conductive oxide (TCO) layer 110 deposited on substrate 105, a window layer 115 made from an n-type semiconductor material, an absorber layer 120 made from a semiconductor material, and a metal back contact 125. Typical devices use cadmium telluride (CdTe) as absorber layer 120 and include glass substrate 105, tin oxide (SnO₂) or cadmium tin oxide (Cd₂SnO₄) as TCO layer 110, and cadmium sulfide (CdS) as the window layer 115. By way of example, a deposition process for a typical photovoltaic device on substrate 105 may be ordered as TCO layer 110 including a n-type material doped with one of SnO₂ and Cd₂SnO₄, CdS window layer 115, a CdTe absorber layer 120, and metal back contact 125. CdTe absorber layer 120 may be deposited on top of window layer 115.

An exemplary energy band diagram of a typical thin-film photovoltaic device, such as a CdTe device is depicted in FIG. 2. Band gap energy for F-doped SnO₂ as TCO layer is depicted as 205, band gap energy of undoped SnO₂ as a buffer layer is depicted as 210, band gap energy of CdS as the window layer is depicted as 215, and band gap energy of CdTe as an absorber layer is depicted as 220. Typically, the conduction band edge offset of CdS relative to CdTe, Δ, is usually −0.2 eV with an experimental uncertainty of +/−0.1 eV.

As depicted in FIG. 2, Δ is the offset in the conduction band edge Ec between the window layer and absorber. In the case of a CdS/CdTe stack, Δ is about −0.2 eV. Theoretical modeling has shown that a more negative Δ leads to larger loss in Voc and FF due to increased rate at which photo carriers recombine at the window/absorber interface. When Δ is made slightly positive (0 to 0.4 eV), the recombination rate can be minimized, leading to improved Voc and FF.

CdS is the conventional window layer in many types of thin-film photovoltaic devices, including photovoltaic devices employing one of CdTe and Cu(In, Ga)Se₂ as an absorber layer. However, as depicted in FIG. 2, the optical band gap for CdS is only 2.4 eV.

### BRIEF DESCRIPTION OF THE DRAWINGS

FIG. 1 depicts a typical photovoltaic device.

FIG. 2 depicts an exemplary energy band diagram of a typical thin-film photovoltaic device.

FIG. 3A depicts a substrate structure according to one embodiment.

FIG. 3B depicts a substrate structure according to another embodiment.

FIG. 4 depicts a substrate structure according to another embodiment.

FIG. 5A depicts a thin-film photovoltaic device according to one embodiment.

FIG. 5B depicts a thin-film photovoltaic device according to another embodiment.

FIG. 6 depicts a thin-film photovoltaic device according to another embodiment.

FIG. 7 depicts an energy band diagram of a thin-film photovoltaic device according to one embodiment.

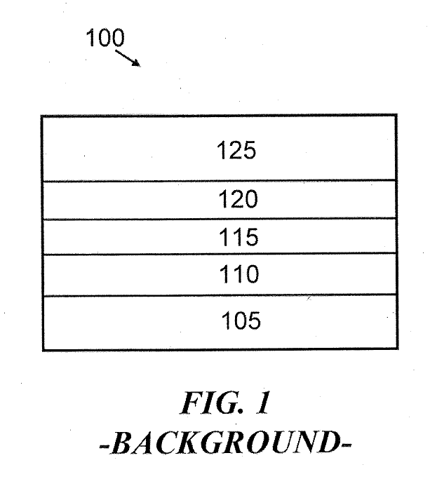

### DETAILED DESCRIPTION OF THE INVENTION

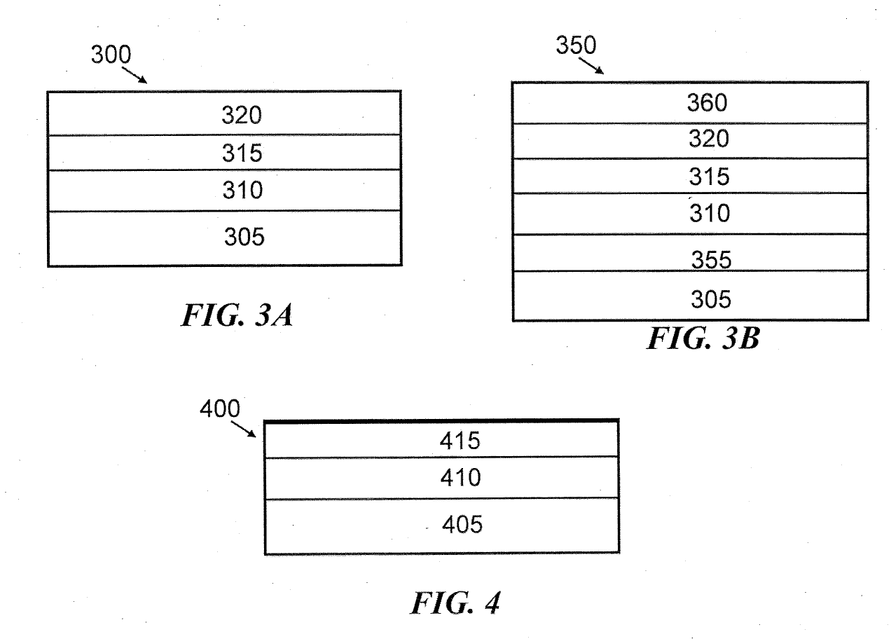

This disclosure is directed to photovoltaic devices and methods of production. In one embodiment, a metal sulfide oxide (MS ₁₋ₓOₓ) compound is employed for a window layer of a substrate structure. FIG. 3 depicts substrate structure 300 according to one embodiment. Substrate structure 300 includes substrate 305, transparent conductive oxide (TCO) layer 310, buffer layer 315 and window layer 320. TCO layer 310 may typically be employed to allow solar radiation to enter a photovoltaic device and may further act as an electrode. TCO layer 310 may include an n-type material doped with one of SnO₂ and Cd₂SnO₄. Window layer 320 may be employed to mitigate the internal loss of photo carriers (e.g., electrons and holes) in the device and may strongly influence device parameters including open circuit voltage (Voc), short circuit current (Isc) and fill factor (FF). In one embodiment, window layer 320 may allow incident light to pass to an absorber material to absorb light. According to one embodiment, to improve overall photo emission efficiency of window layer 320, substrate structure 300 includes a MS ₁₋ₓOₓ compound. A metal sulfide oxide (MS₁₋ₓOₓ) compound material as described herein may include one or more materials, where the metal (M) may include one of zinc (Zn), tin (Sn) and indium (In).

In one embodiment, substrate structure 300 may include a glass substrate 305, and TCO layer 310, wherein buffer layer 315 may be omitted. Window layer 320 (e.g., MS₁₋ₓOₓ layer) may be directly on top of TCO layer 310, the TCO layer relating to one or more of a F-doped SnO₂, undoped SnO₂, and Cd₂SnO₄. When TCO layer 310 is an undoped Cd₂SnO₄, the TCO layer has no extrinsic dopant, however the layer may be highly n-type due to oxygen vacancies.

According to another embodiment, substrate structure 300 may be provided for manufacturing photovoltaic devices. As depicted in FIG. 3A, the substrate structure includes substrate 305, TCO layer 310, low conductivity buffer layer 315, and MS ₁₋ₓOₓ window layer 320. The substrate structure of FIG. 3A includes MS₁₋ₓOₓ window layer 320 onto which other necessary layers of a device can be deposited (e.g., absorber layer, metal back, etc.). In one embodiment, MS ₁₋ₓOₓ window layer 320 may be deposited onto an F-SnO₂ based substrate structure (like TEC10). Similarly, such substrate structure 300 can be a cadmium stannate (CdSt) substrate structure. Buffer layer 315 may be used to decrease the likelihood of irregularities occurring during the formation of the semiconductor window layer. Buffer layer 315 may be made from a material less conductive than TCO layer 310, such as undoped tin oxide, zinc tin oxide, cadmium zinc oxide or other transparent conductive oxide or a combination thereof. In certain embodiments, substrate structure 300 may not include a buffer layer as depicted in FIG. 4. When substrate structure 300 includes a low conductivity buffer layer 315, the buffer layer is arranged between the substrate 305 (e.g., glass) and the MS₁₋ₓOₓ window layer.

In one embodiment the thickness of MS₁₋ₓ,Oₓ window layer 320 ranges from 2 to 2000 nm. In another embodiment, the composition of x in MS₁₋ₓOₓ is greater than 0 and less than 1. Window layer 320 may be a more conductive material relative to conventional window layer materials, such as CdS. Additionally, window layer 320 may include a window layer material that allows for greatly reduced fill factor (FF) loss in a blue light deficient environment. A MS₁₋ₓOₓ window layer may allow for more solar radiation in the blue region (e.g., 400 to 475 nm) that can reach the absorber leading to higher short circuit current (Isc).

In an alternative embodiment, a photovoltaic device, such as substrate structure 300 may include a MS₁₋ₓOₓ compound material as window layer 320 and one or more of a barrier layer and a CdS window layer, as depicted in FIG. 3B. Barrier layer 355 of substrate structure 350 can be silicon oxide, silicon aluminum oxide, tin oxide, or other suitable material or a combination thereof. CdS window layer 360 may be deposited on MS₁₋ₓOₓ layer 320, wherein CdS window layer 360 relates to a surface for depositing an absorber layer. In one embodiment, a photovoltaic device includes a MS₁₋ₓOₓ window layer, in addition to a substrate structure (e.g., substrate structure 300). For example, substrate structure 300 may include to a TCO stack including a substrate 305, TCO layer 310, and one or more additional elements. In another embodiment, substrate structure 300 may include buffer layer 315.

Advantages of employing MS₁₋ₓOₓ in the window layer of a photovoltaic device may include improved open circuit voltage (Voc) relative to a device having a CdS window layer. The improvement in device Voc employing a MS₁₋ₓOₓ window layer in comparison to a device having a CdS window layer, for example, may improve open circuit voltage from 810 mV to 826 mV. A CdTe device with MS₁₋ₓOₓ window layer may additionally utilize a higher quantum efficiency relative to a photovoltaic device having a CdS window layer from 400-475 nm. The values of Voc improvements described herein are exemplary, as it may be difficult to measure a certain improvement delta. Source current may improve up to 2 mA/cm², wherein the improvement compared to a photovoltaic device having a CdS window layer may depend on the thickness of CdS employed.

Referring to FIG. 4, a substrate structure of FIG. 3A is depicted according to another embodiment. Substrate structure 400 includes substrate 405, TCO layer 410, and MS₁₋ₓOₓ window layer 415. Substrate structure 400 may be manufactured at lower cost in comparison to the substrate structure 300 of FIG. 3A.

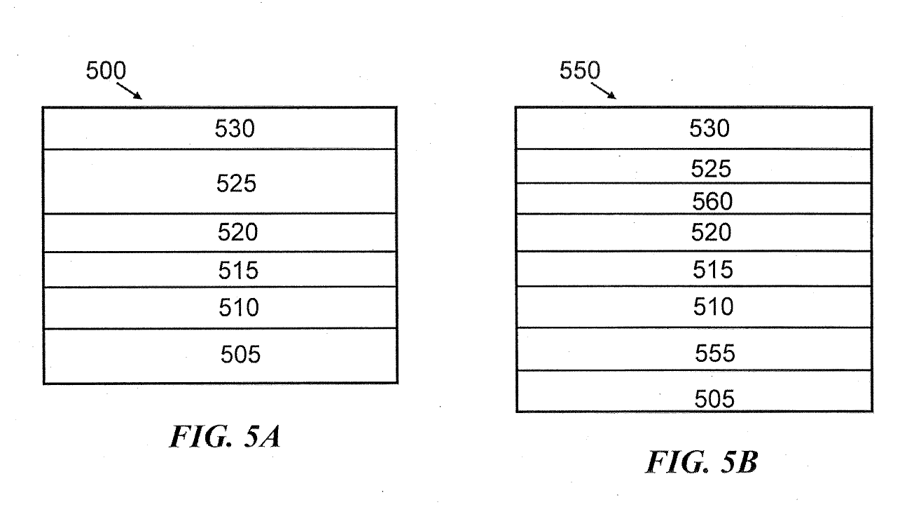

According to another embodiment, MS₁₋ₓOₓ may be employed for a window layer of a thin-film photovoltaic device. FIGS. 5A-5B depict a thin-film photovoltaic devices according to one or more embodiments. Referring first to FIG. 5A, thin-film photovoltaic device 500 includes substrate 505, transparent conductive oxide (TCO) layer 510, buffer layer 515, window layer 520, absorber layer 525, and metal back 530. Absorber layer 525 may be employed to generate photo carriers upon absorption of solar radiation. Metal back contact 530 may be employed to act as an electrode. Metal back contact 530 may be made of molybdenum, aluminum, copper, or any other highly conductive materials. Window layer 520 of thin-film photovoltaic device 500 may include a MS₁₋ₓOₓ compound.

More specifically, thin-film photovoltaic device 500 may include one or more of glass substrate 505, TCO layer 510 made from SnO₂ or Cd₂SnO₄, buffer layer 515, a MS₁₋ₓOₓ window layer 520, a CdTe absorber 525, and a metal back contact 530. Buffer layer 515 may be a low conductivity buffer layer, such as undoped SnO₂. Buffer layer 515 may be used to decrease the likelihood of irregularities occurring during the formation of the semiconductor window layer. Absorber layer 525 may be a CdTe layer. The layer thickness and materials are not limited by the thicknesses depicted in FIGS. 5A-5B. In one embodiment, the device of FIG. 5A may employ the substrate of FIG. 3A.

Thin-film photovoltaic device 500 may include one or more of a cadmium telluride (CdTe), copper indium gallium (di)selenide (CIGS), and amorphous silicon (Si) as the absorber layer 525. In one embodiment, a thin-film photovoltaic device may be provided that includes a MS₁₋ₓOₓ window layer 520 between a substrate structure 505, which may or may not include a low conductivity buffer layer 515, and the absorber layer 525. In certain embodiments, the device may additionally include a CdS window layer in addition to MS₁₋ₓOₓ window layer 520.

In an alternative embodiment, thin-film photovoltaic device 500 may include a MS₁₋ₓOₓ compound material as window layer 520 and one or more of a barrier layer and a CdS window layer, as depicted in FIG. 58. Barrier layer 555 can be silicon oxide, silicon aluminum oxide, tin oxide, or other suitable material or a combination thereof. CdS window layer 560 may be deposited on MS₁₋ₓOₓ layer 520, wherein CdS window layer 560 provides a surface for depositing an absorber layer.

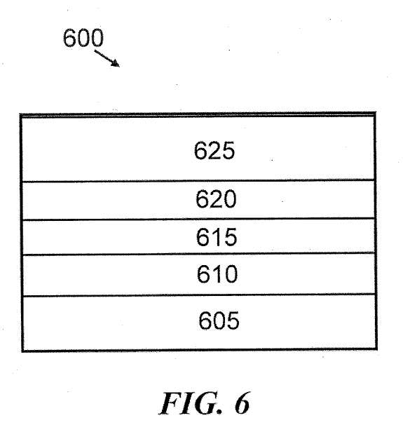

In certain embodiments, thin-film photovoltaic device 500 may not include a buffer layer. FIG. 6 depicts thin-film photovoltaic device 600 which includes glass substrate 605, TCO layer 610 made from SnO₂ or Cd₂SnO₄, a MS₁₋ₓOₓ window layer 615, a CdTe absorber 620, and a metal back contact 625.

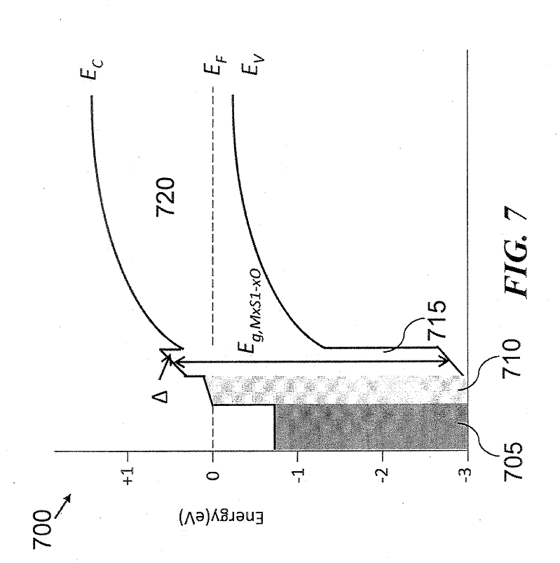

FIG. 7 depicts the band structure of a thin-film photovoltaic device, such as a photovoltaic device which employs a CdTe absorber layer, according to one embodiment. In FIG. 7, band gap energy depicted for F-doped SnO₂ as a TCO layer is depicted as 705, undoped SnO₂ as a buffer layer is depicted as 710, MS₁₋ₓOₓ as the window layer is depicted as 715, and CdTe as the absorber layer is depicted as 720. As further depicted, the conduction band edge offset of MS₁₋ₓOₓ relative to CdTe, Δ, can be adjusted to 0-0.4 eV. Another advantage of the thin-film photovoltaic device of FIG. 3 may be a wider band gap in comparison to CdS.

All oxide and sulfide compounds of zinc, tin or indium (e.g., MS₁₋ₓOₓ), have a band-gap similar or larger than that of CdS, which is 2.4 eV. The ternary compound MS₁₋ₓOₓ can have a wider band gap (e.g., greater then 2.4 eV) when x is properly chosen. As a result, a MS₁₋ₓOₓ compound may allow for greater transparency with respect to blue light. On the other hand, all oxides of M have a negative Δ relative to the CdTe conduction band edge, while all sulfides have a positive Δ. Therefore, the composition of the ternary compound MS₁₋ₓOₓ can be tuned to a Δ that is slightly positive, as shown in FIG. 4, with ZnS₁₋ₓOₓ shown as an example.

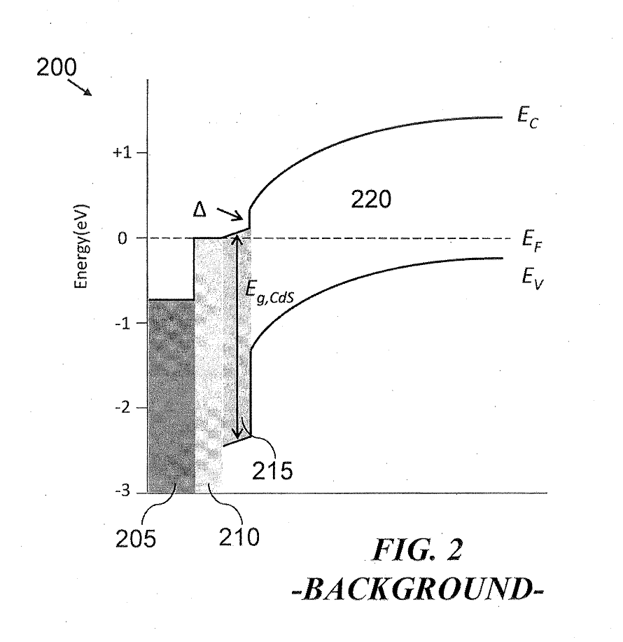

In another aspect, a process is provided for manufacturing photovoltaic devices and substrates to include a MS₁₋ₓOₓ window layer as depicted in FIGS. 2 and 3. Substrate structure 200, containing a MS₁₋ₓOₓ window layer, may be manufactured by one or more processes, wherein one or more layers of the structure may be manufactured by one or more of sputtering, evaporation deposition, and chemical vapor deposition (CVD). Similarly, thin-film photovoltaic device 300, containing a MS₁₋ₓOₓ window layer, may be manufactured by one or more the following processes, including sputtering, evaporation deposition, CVD, chemical bath deposition and vapor transport deposition.

In one embodiment, a process for manufacturing a photovoltaic device may include a sputtering process of a MS₁₋ₓOₓ window layer by one of DC Pulsed sputtering, RF sputtering, AC sputtering, and other manufacturing processes in general. The source materials used for sputtering can be one or more ceramic targets of a MS₁₋ₓOₓ ternary compound, where x is in the range of 0 to 1. In one embodiment, source materials used for sputtering can be one or more targets of MS₁₋ₓOₓ alloy, where x is in the range of 0 to 1. In another embodiment, source materials used for sputtering can be or two or more ceramic targets with one or more made from the oxide of M and the one or more made from the sulfide of M. Process gas for sputtering the MS₁₋ₓOₓ can be a mixture of argon and oxygen using different mixing ratios.

In one embodiment, a MS₁₋ₓOₓ window layer can be deposited by atmospheric pressure chemical vapor deposition (APCVD) with precursors including but not limited to diethyl zinc, diethyl tin, and trimethyl indium with a combination of reagents such as H₂O/H₂S, or ozone/H₂S.

According to another embodiment, the process for manufacturing a photovoltaic device may result in a conduction band offset with respect to an absorber layer. For example, the conduction band offset of a window (MS₁₋ₓOₓ) layer with respect to the absorber layer can be adjusted between 0 and +0.4 eV by choosing the value of x. Further, improved conductivity can be achieved by doping MS₁₋ₓOₓwith cation impurities with a valence higher than that of the metal cation (M), such as aluminum (Al), chromium (Cr), niobium (Nb) and manganese (Mn) doping of ZnS₁₋ₓOₓ, or with monovalant anion impurities such as fluorine (F), and by introduction of oxygen vacancies (e.g., lowering oxygen partial pressure during sputtering). In one embodiment the dopant concentration is from about 1×10¹⁴ cm³ to about 1×10¹⁹ cm³. In one embodiment, the window layer is formed using a sputter target having a dopant concentration from about 1×10¹⁷ cm³ to about 1×10¹⁸ cm³.

What is claimed is:

1. A photovoltaic device comprising:
a substrate;
a MS₁₋ₓOₓ window layer formed over the substrate, wherein M is Zn; and
an absorber layer formed over the substrate.

2. The photovoltaic device of claim 1, wherein the absorber layer is CdTe.

3. The photovoltaic device of claim 1, wherein the absorber layer is CICS.

4. The photovoltaic device of claim 1, wherein the absorber layer is amorphous Si.

5. The photovoltaic device of claim 1, wherein the MS₁₋ₓOₓ window layer is formed between the substrate and the absorber layer.

6. The photovoltaic device of claim 1, further comprising a CdS window layer disposed between MS₁₋ₓOₓ window layer and the absorber layer.

7. The photovoltaic device of claim 1, wherein a conduction band offset of the MS₁₋ₓOₓ layer with respect to the absorber layer is in the range of from about 0 to about +0.4 eV.

8. A photovoltaic device comprising:
a substrate;
a MS₁₋ₓOₓ window layer formed over the substrate, wherein M is Sn; and
an absorber layer formed over the substrate.

9. The photovoltaic device of claim 8, wherein the absorber layer is CdTe.

10. The photovoltaic device of claim 8, wherein the absorber layer is CIGS.

11. The photovoltaic device of claim 8, wherein the absorber layer is amorphous Si.

12. The photovoltaic device of claim 8, wherein a conduction band offset of the MS₁₋ₓOₓ layer with respect to the absorber layer is in the range of from about 0 to about +0.4 eV.

13. A photovoltaic device comprising:
a substrate;
a MS₁₋ₓOₓ window layer formed over the substrate, wherein M is In; and
an absorber layer formed over the substrate.

14. The photovoltaic device of claim 13, wherein the absorber layer is CdTe.

15. The photovoltaic device of claim 13, wherein the absorber layer is CIGS.

16. The photovoltaic device of claim 13, wherein the absorber layer is amorphous Si.

17. The photovoltaic device of claim 13, wherein a conduction band offset of the MS₁₋ₓOₓ layer with respect to the absorber layer is in the range of from about 0 to about +0.4 eV.

18. A process for manufacturing a photovoltaic device comprising:
forming a MS₁₋ₓOₓ window layer over a substrate, wherein M is one of Zn, Sn and In; and
forming an absorber layer over the substrate.

19. The process of claim 18, wherein the MS₁₋ₓOₓ layer is formed by at least one of sputtering, evaporation deposition, CVD, chemical bath deposition process and vapor transport deposition process.

20. The process of claim 18, a conduction band offset of MS₁₋ₓOₓ layer with respect to the absorber layer is in the range of from about 0 to about +0.4 eV.

21. A photovoltaic device comprising:
a substrate;
a MS₁₋ₓOₓ window layer formed over the substrate by at least one of a sputtering process, evaporation deposition process, CVD process, chemical bath deposition process and vapor transport deposition process, wherein M is an element from the group consisting of Zn, Sn, and In; and
an absorber layer formed on the substrate, wherein the absorber layer is formed from one of CdTe, CIGS, and amorphous Si.

22. The photovoltaic device of claim 21, wherein the sputtering process of the MS₁₋ₓOₓ window layer is one of DC Pulsed sputtering, RF sputtering, and AC sputtering.

23. The photovoltaic device of claim 21, wherein source materials used for sputtering is two or more ceramic targets with one or more made from the oxide of M, and one or more made from the sulfide of M.

24. The photovoltaic device of claim 21, wherein the process gas for sputtering the MS₁₋ₓOₓ is a mixture of Argon and Oxygen.

25. The photovoltaic device of claim 21, wherein the MS₁₋ₓOₓ layer is deposited by APCVD with precursors including but not limited to diethyl zinc, diethyl tin, and trimethyl indium with a combination of reagents such as H₂O/H₂S, or ozone/H₂S.

26. The photovoltaic device of claim 21, wherein the conduction band offset of the MS₁₋ₓOₓ layer with respect to the absorber layer is in the range of 0 to +0.4 eV.

27. The photovoltaic device of claim 21, wherein the conductivity of the MS₁₋ₓOₓ layer is within a range of 1 mOhm per cm to 10 Ohm per cm.

28. The photovoltaic device of claim 21, wherein the MS₁₋ₓOₓ layer is doped with cations of higher valence than that of M, or with monovalent anions, such as F, or with oxygen vacancies.
